(19) United States
(12) Patent Application Publication
(10) Pub. No.: US 2026/0155559 A1
(43) Pub. Date: Jun. 4, 2026

(54) NEAR-FIELD COMMUNICATION DEVICE INTENDED TO BE INTEGRATED IN A MOTOR VEHICLE

(71) Applicant: SCHAEFFLER TECHNOLOGIES AG & CO. KG, Herzogenaurach (DE)

(72) Inventors: Xavier HOURNE, Toulouse (FR); Olivier GERARDIERE, Toulouse (FR); Olivier DOUSSIN, Toulouse (FR)

(73) Assignee: SCHAEFFLER TECHNOLOGIES AG & CO. KG, Herzogenaurach (DE)

(21) Appl. No.: 19/123,985

(22) PCT Filed: Dec. 5, 2023
(86) PCT No.: PCT/EP2023/084207

§ 371 Date: Apr. 24, 2025

(30) Foreign Application Priority Data
Dec. 7, 2022 (FR) FR2212876

(51) Int. Cl. H01Q 1/32; B60R 25/24; E05B 81/76; H01Q 7/00; H05K 1/02; H05K 1/16

(52) U.S. Cl. CPC H01Q 1/3208; E05B 81/76; H01Q 1/3241; H01Q 7/00; H05K 1/0298; H05K 1/16; B60R 25/245; H05K 2201/10098

(57) ABSTRACT

A near-field communication device intended to be integrated in a motor vehicle and including: a printed circuit board having at least four functional layers made of electrically conductive material, separated from each other by insulating layers made of dielectric material; a near-field communication antenna, formed by four concentric turns integrated on the printed circuit board; and at least one electronic power supply and signal-processing circuit connected to the antenna and integrated on the printed circuit board. The four turns are distributed over only two adjacent functional layers, this reducing a drift in the inductance of the antenna, from one device to the other.

### CROSS REFERENCE TO RELATED APPLICATIONS

This application is the U.S. National Phase Application of PCT International Application No. PCT/EP2023/084207, filed Dec. 5, 2023, which claims priority to French Patent Application No. FR2212876, filed Dec. 7, 2022, the contents of such applications being incorporated by reference herein.

### FIELD OF THE INVENTION

The invention relates to the automotive field and more particularly to a near-field communication device intended to be integrated in a motor vehicle.

In practice, such a device belongs to a vehicle-access system having functions for authenticating and locating a user with the aid in particular of communication between the vehicle and a badge carried by the user. The badge may be a dedicated device. As a variant, it may be a smartphone integrating a dedicated functionality.

### BACKGROUND OF THE INVENTION

The prior art discloses near-field communication devices intended to be integrated in a motor vehicle and comprising:
a printed circuit board;
a near-field communication antenna integrated on the printed circuit board; and
at least one electronic power supply and signal-processing circuit connected to the antenna and integrated on the printed circuit board.

The near-field communication antenna is formed of a plurality of concentric turns which together form a coil.

In use, the coil is flown through by an electric current which generates an electromagnetic field oriented in a direction orthogonal to the plane of the turns. Electromagnetic coupling between two adjacent near-field communication antennas allows data exchange, or communication, to be carried out between these two antennas. In particular, the current flowing through one coil, or antenna, will generate a magnetic field which will pass through the other coil, or antenna, and generate a current therein.

The electromagnetic field generated decreases very quickly as it moves away from the antenna, hence the notion of near field. A maximum communication distance between two near-field communication antennas is preferably less than 10 cm, or even less than 5 cm.

A near-field communication antenna therefore designates an antenna which is configured to transmit and receive an electromagnetic signal by electromagnetic coupling with another near-field communication antenna. For short, a near-field communication antenna can be referred to as an NFC antenna, the term “NFC” possibly also designating a particular communication protocol implemented in a near-field communication antenna.

Optimization studies have shown that, in the case of a near-field communication device intended to be integrated in a motor vehicle to form part of a vehicle-access system, a near-field communication antenna composed of exactly four turns results in optimal performance. For example, an antenna with only two turns does not make it possible to achieve a sufficient inductance value to operate the near-field communication device as part of a vehicle-access system.

Advantageously, the near-field communication antenna is integrated on a multilayer printed circuit board. A multilayer printed circuit board is formed of an alternation of so-called functional layers, made of electrically conductive material, and so-called insulating layers, made of dielectric material.

In a manner known per se, the efficiency of the near-field communication antenna is proportional to the square of the surface it surrounds. The person skilled in the art therefore seeks to dimension and arrange the four turns so as to maximize the surface delimited by an internal contour of the antenna.

In order to reconcile this objective with the search for high compactness, the four turns are formed in a printed circuit board comprising four or more functional layers which are superposed one on top of the other each in a respective functional layer.

An aspect of the invention aims to optimize the performance of a near-field communication device intended to be integrated in a motor vehicle and incorporating a near-field communication antenna.

### SUMMARY OF THE INVENTION

This aspect is achieved with a near-field communication device intended to be integrated in a motor vehicle and comprising:
a printed circuit board comprising at least four superposed so-called functional layers made of electrically conductive material, separated from each other by respective so-called insulating layers made of dielectric material;
a near-field communication antenna, formed by four concentric turns integrated on the printed circuit board; and
at least one electronic power supply and signal-processing circuit connected to the antenna and integrated on the printed circuit board.

The electronic power supply and signal-processing circuit designates an electronic circuit configured to:
generate an electrical transmission signal intended to be transformed by the antenna into a magnetic transmission signal (power supply function of the antenna); and
carry out signal (pre)processing on an electrical signal received, provided by the antenna and corresponding to a magnetic signal received by the antenna and transformed by the latter into an electrical signal (signal-processing function, comprising at least one demodulation and one amplification).

According to an aspect of the invention, the four turns are distributed over only two adjacent functional layers of the printed circuit board.

This arrangement is therefore totally contrary to the prejudices of the person skilled in the art who up to now thought that the optimal arrangement consisted in stacking the four turns one on top of the other in order to combine great compactness and a large surface inscribed inside the antenna.

The inventors have noticed that, in a device with the four stacked turns, the inductance of the near-field communication antenna varies in a non-negligible manner from one device to the other.

These variations in inductance induce significant variations in the impedance seen by the electronic power supply and signal-processing circuit, from one device to the other. This results in variations in impedance matching between the antenna and said circuit, from one device to the other. Ultimately, this therefore results in variations in the performance of the near-field communication device, from one device to the other.

The inventors then realized that these variations in inductance were related to variations in thickness of the various layers of the printed circuit board, from one device to the other. In particular, there is a certain manufacturing tolerance on the thickness of each layer of the printed circuit board. This results in slight variations in the distance between two adjacent turns, from one device to the other, and therefore variations in the inductance of the near-field communication antenna, from one device to the other.

The inventors then had the idea of proposing a device in which the four turns are no longer distributed over four superposed layers of a printed circuit board but over only two adjacent functional layers of the printed circuit board, with the printed circuit board which still comprises four or more functional layers.

Thus, the accumulation of the variations in distance between two adjacent turns is reduced, by construction, this also limiting the variations in inductance from one device to the other. In particular, the variation in inductance of the antenna, from one device to the other, depends on the variation in thickness of a single layer of the printed circuit (the insulating layer located between the two adjacent functional layers receiving the turns) and not on the sum of the variations in thickness of three superposed insulating layers interposed between the four functional layers receiving the turns.

An aspect of the invention thus proposes an arrangement of the turns which is totally counter-intuitive and contrary to the prejudices of the person skilled in the art. This arrangement makes it possible, surprisingly, to limit the variation in inductance of the near-field communication antenna, from one device to the other. This thus limits variations in the impedance matching with the electronic power supply and signal-processing circuit, from one device to the other. Ultimately, this thus limits variations in the performance of the near-field communication device, from one device to the other. This thus ensures, for example, that all devices in the same production line have the same performance, in particular in terms of communication distance.

An aspect of the invention thus proposes a robust design with a very low drift in the parameters of the antenna from one device to the other.

The overall size is kept almost identical for the same efficiency of the near-field communication antenna since the turns remain distributed in two layers and are not all coplanar.

Preferably, the antenna is formed by four turns, with two first turns located on a first functional layer and two second turns located on a second functional layer, the first functional layer and the second functional layer being separated from each other by a single insulating layer.

Advantageously, the two first turns are superposed in pairs with the two second turns.

Said two adjacent functional layers preferably include an end layer of the printed circuit board.

The at least one electronic power supply and signal-processing circuit is advantageously formed in at least one functional layer of the printed circuit board that is distinct from the functional layers receiving the turns.

The at least one electronic power supply and signal-processing circuit may be inscribed inside a surface delimited by an internal contour of the turns.

The device according to an aspect of the invention may further comprise a capacitive electrode which is inscribed inside a surface delimited by an internal contour of the turns and which is connected to a detection circuit to form a capacitive presence sensor, with the detection circuit integrated on the printed circuit board.

Each turn is advantageously square in shape.

An aspect of the invention also covers a door handle for a motor vehicle, comprising a device according to an aspect of the invention.

### BRIEF DESCRIPTION OF THE DRAWINGS

Further features and advantages of aspects of the invention will become more clearly apparent upon reading the following description. This description is purely illustrative and should be read with reference to the appended drawings, in which:

FIG. 1A schematically illustrates, in a sectional view, a near-field communication device intended to be integrated in a motor vehicle, according to the prior art;

FIG. 1B schematically illustrates, in a plan view, one of the functional layers of the device of FIG. 1A;

FIG. 2A schematically illustrates, in a sectional view, a near-field communication device according to an aspect of the invention;

FIG. 2B schematically illustrates, in a plan view, a first of the functional layers receiving the near-field communication antenna, in the device of FIG. 2A;

FIG. 2C schematically illustrates, in a plan view, a second of the functional layers receiving the near-field communication antenna, in the device of FIG. 2A;

FIG. 2D schematically illustrates, in a transparent plan view, the device of FIG. 2A; and

FIG. 3 schematically illustrates a comparison of the variation in inductance from one device to the other, in devices similar to those of FIGS. 1A and 1B and in devices similar to those of FIGS. 2A to 2D.

### DETAILED DESCRIPTION OF AT LEAST ONE EMBODIMENT

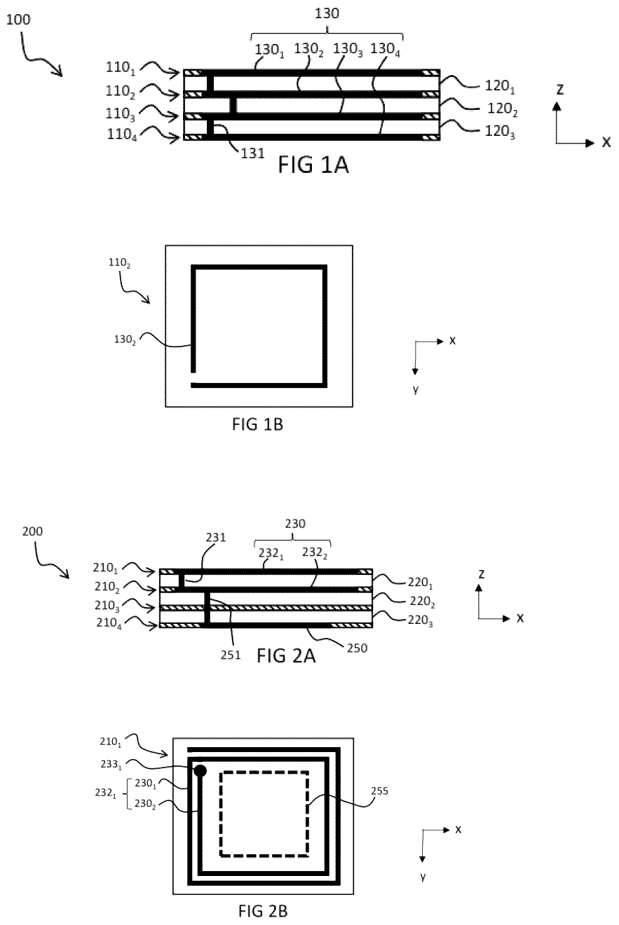

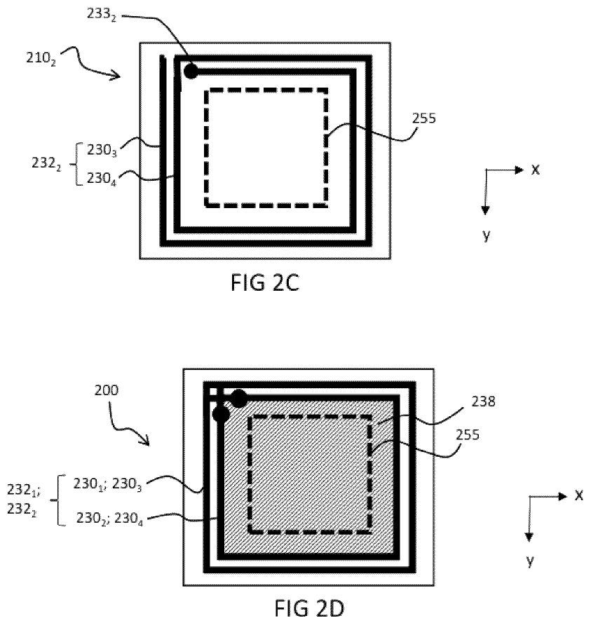

FIGS. 1A to 2D show the axes of an orthonormal reference frame (0xyz) to facilitate understanding.

A description will first be given briefly, and with reference to FIGS. 1A and 1B, of a near-field communication device 100 according to the prior art, intended to be integrated in a motor vehicle and to form part of a vehicle-access system.

In FIG. 1A, the near-field communication device 100 is shown, schematically, in a sectional view in a plane parallel to the plane (x0z).

The device 100 comprises a printed circuit board, here composed of four so-called functional layers 110₁, 110₂, 110₃, 110₄ between which insulating layers 120₁, 120₂, 120₃ are interposed.

The functional layers 110₁, 110₂, 110₃, 110₄ are formed by electrically conductive metal tracks. They each extend parallel to the plane (0xy) and are stacked one on top of the other along the axis (0z).

The functional layers 110₁, 110₂, 110₃, 110₄ are separated from each other by the insulating layers 120₁, 120₂, 120₃ made of dielectric material. The insulating layers 120₁, 120₂, 120₃ each extend parallel to the plane (0xy) and are stacked one on top of the other along the axis (0z). A respective insulating layer is interposed between two adjacent functional layers, in direct physical contact with each of said functional layers.

The device 100 comprises a near-field communication antenna 130, comprising four superposed turns 130₁, 130₂, 130₃, 130₄ each located in a respective one of the functional layers 110₁, 110₂, 110₃, 110₄. The turns are connected to one another by vertical vias 131 oriented along the axis (0z) and each passing through at least one insulating layer 120₁, 120₂, 120₃.

Each turn is formed by a respective metal track in the corresponding functional layer. FIG. 1B schematically illustrates one of the functional layers of the device 100, here the functional layer 110₂ receiving the turn 130₂.

Each of the turns 130₁, 130₂, 130₃, 130₄ has a substantially rectangular or square shape.

Next, with reference to FIGS. 2A to 2D, a near-field communication device 200 according to an aspect of the invention, intended to be integrated in a motor vehicle and to form part of a vehicle-access system, is illustrated.

The device 200 will be described only in terms of its differences in relation to the device of FIGS. 1A and 1B.

As in the prior art, the device comprises a printed circuit board comprising an alternation of functional layers 210₁, 210₂, 210₃, 210₄ and of insulating layers 220₁, 220₂, 220₃ as described above, with at least four functional layers.

The device 200 comprises a near-field communication antenna 230 comprising four turns distributed in only two of the functional layers.

In particular, the four turns are distributed in two adjacent functional layers which are separated by a single insulating layer.

Advantageously, and as illustrated in FIG. 2A, the four turns are distributed in two functional layers including an end functional layer of the printed circuit board. An end functional layer of the printed circuit board designates a functional layer located at one end of the stack of functional and insulating layers which together form the printed circuit board. A functional end layer is only in contact with an insulating layer at only one of its two large faces.

Here, the four turns are distributed in the functional layers 210₁ and 210₂.

The four turns are distributed in two pairs of turns 232₁, 232₂ located in the layers 210₁ and 210₂, respectively, and arranged superposed. The pairs of turns are connected together by a vertical via 231 oriented along the axis (0z) and passing through at least the insulating layer 220₁ (in the direction of the thickness).

Each pair of turns 232₁, 232₂, respectively, is formed of two concentric and coplanar turns.

FIG. 2B schematically illustrates the functional layer 210₁ receiving the pair of turns 232₁.

As illustrated by FIG. 2B, the pair of turns 232₁ is composed of two turns 230₁ and 230₂ wound one around the other. In other words, the two turns 230₁ and 230₂ are formed by a single linear metal strip formed in the functional layer 210₁.

Each turn 230₁ and 230₂ is substantially square or rectangular in shape. In particular, each turn 230₁ and 230₂ is in the form of a rectangle or square which is open because of the arrangement of the turns wound one around the other.

In FIG. 2B, one terminal of the near-field communication antenna 230 is also represented by a black circle 233₁.

FIG. 2C schematically illustrates the functional layer 210₂ receiving the pair of turns 232₂.

As illustrated by FIG. 2C, the pair of turns 232₂ is composed of two turns 230₃ and 230₄ wound one around the other. In other words, the two turns 230₃ and 230₄ are formed by a single linear metal strip formed in the functional layer 210₂.

Each turn 230₃ and 230₄ is substantially square or rectangular in shape. In particular, each turn 230₃ and 230₄ is in the form of a rectangle or square which is open because of the arrangement of the turns wound one around the other.

In FIG. 2C, the other terminal of the near-field communication antenna 230 is also represented by a black circle 233₂.

FIG. 2D schematically illustrates, and in a transparent plan view, the device 200.

In FIG. 2D, the insulating layers are shown transparent so that the superposition of the two pairs of turns 232₁ and 232₂ can be seen. As illustrated by FIG. 2D, each turn of the first pair of turns 232₁ is superposed with a respective one of the turns of the second pair of turns 232₂.

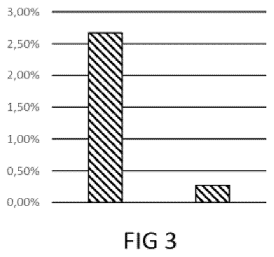

FIG. 3 shows variations in inductance of the near-field communication antenna, from one device to the other. The inductance variation values were obtained by simulation.

The bar on the left shows the variation in inductance in a device of the prior art as described in the introduction, formed on a printed circuit board of 0.8 mm in thickness. The variation in inductance is of the order of 2.5%.

The bar on the right shows the variation in inductance in a device according to an aspect of the invention, formed on a printed circuit board also of 0.8 mm in thickness. The variation in inductance is of the order of 0.25%.

Here, it can be seen that the variations in inductance of the near-field communication antenna, from one device to the other, are reduced by a factor of 10. This confirms the inventors'intuition that the variations in inductance can be reduced by limiting the number of layers over which the turns of the antenna extend. Various simulations have been performed. In all cases, the variations in inductance are reduced by a factor of between 3 and 10.

According to an aspect of the invention, the device 200 further comprises at least one electronic power supply and signal-processing circuit 250.

As detailed in the introduction, the electronic power supply and signal-processing circuit 250 is configured to generate an electrical transmission signal intended to be transformed by the antenna 230 into a magnetic transmission signal, and to carry out signal preprocessing on an electrical signal provided by the antenna 230 and corresponding to a magnetic signal received by said antenna 230 and transformed by the latter into an electrical signal. The signal preprocessing comprises in particular demodulation and amplification of the electrical signal provided by the antenna 230, in order to be able to then extract useful information therefrom. The electronic circuit 230 may be called a “transmit and receive circuit”, or simply a “transceiver”. The electronic power supply and signal-processing circuit comprises a transmission stage, a reception stage (demodulation, amplification), and possibly a signal-processing stage (for extracting useful information).

The circuit 250 is connected to the antenna 230 by at least one vertical via 251 oriented along the axis (0z). It has at least one function of supplying power to the antenna 230 and of receiving and processing an electrical signal provided by the antenna 230.

The circuit 250 extends in at least one functional layer of the printed circuit board that is distinct from a layer receiving one or more turns of the antenna. Here, the circuit 250 extends into the functional layer 2104 furthest away from the antenna 230. In variants which are not shown, the circuit 250 extends in a plurality of superposed functional layers that are all distinct from a layer receiving one or more turns of the antenna. Advantageously, the circuit 250 extends, at least, in the functional layer furthest away from the antenna 230.

FIGS. 2B to 2D schematically show the contour 255 of the circuit 250, shown transparent.

Advantageously, and as shown in FIGS. 2B to 2D, the circuit 250 is placed inside the turns. In other words, the circuit 250 is inscribed inside a surface 238 delimited by an internal contour of the turns. In yet other words, according to a representation in plan view, the circuit 250 is inscribed inside the surface 238 delimited by an internal contour of the turns. In yet other words, in an orthogonal projection of the turns and of the circuit 250 in the same plane parallel to the plane (0xy), the projection of the circuit 250 is located inside a surface delimited by the internal contour of the projection of the turns. In FIG. 2D, the surface 238 is shown hatched.

This arrangement offers optimum compactness.

In variants which are not shown, the device according to an aspect of the invention further comprises a capacitive electrode, also inscribed inside a surface delimited by the internal contour of the turns.

Where appropriate, the capacitive electrode and the electronic power supply circuit are arranged superposed, each in at least one distinct layer of the printed circuit board.

Such a capacitive electrode is used, in a manner known per se, to form a measuring capacitor with ground so as to carry out presence detection.

The capacitive electrode is advantageously connected to a detection circuit, not shown, comprising a microcontroller, switches, and a discharge capacitor. The measuring capacitor defined between the capacitive electrode and ground, and the discharge capacitor, are mounted together in a capacitive divider bridge (or “capacitive voltage divider”) arrangement. The switches are controlled in such a way that the measuring capacitor is alternately charged and discharged into the discharge capacitor. When the measuring capacitor is discharged into the discharge capacitor, the charges balance between the two capacitors and it is possible to detect the presence of a target as a function of a voltage signal that is representative of the discharging of the measuring capacitor.

An aspect of the invention also covers a door handle for a motor vehicle, not shown, incorporating a device according to an aspect of the invention such as that described with reference to FIGS. 2A to 2D.

The device according to an aspect of the invention is configured to communicate with an ancillary device carried by a user, the ancillary device also being provided itself with a near-field communication antenna and comprising a memory storing a user identifier. The ancillary device may be a smartphone integrating a specific functionality, or a dedicated device such as a vehicle-access badge.

Advantageously, the electronic power supply and signal-processing circuit 250 is configured to generate the sending of an interrogation signal, from the device according to an aspect of the invention to the ancillary device, the interrogation signal being designed to request the sending of data relating to an identifier stored in the ancillary device.

Advantageously, the electronic power supply and signal-processing circuit 250 is configured to process an electrical identification signal provided by the antenna 230. The electrical identification signal corresponds to the transduction, by the antenna 230, of a magnetic identification signal into an electrical identification signal. The electrical identification signal encodes information relating to an identifier stored in the ancillary device.

The electronic power supply and signal-processing circuit 250 may be configured to extract, from the electrical identification signal, data relating to an identifier stored in the ancillary device, and to transmit this data to a central controller which compares this data with a list of at least one authorized identifier, and generates a command to unlock an opening element when said data corresponds to at least one authorized identifier.

The invention is not limited to the examples illustrated by the figures. For example, in variants which are not shown, the printed circuit board comprises more than four functional layers, for example six. In this case, the near-field communication antenna remains distributed in only two functional layers of the printed circuit board, preferably two adjacent layers including an end layer of the printed circuit board.

In variants of the invention which are less preferred, the four turns are distributed with three turns in a first functional layer and a single turn in a second functional layer, the first functional layer and the second functional layer being separated from each other by a single insulating layer.

1. A near-field communication device intended to be integrated in a motor vehicle and comprising:
a printed circuit board comprising at least four superposed so-called functional layers made of electrically conductive material, separated from each other by respective so-called insulating layers made of dielectric material;
a near-field communication antenna, formed by four concentric turns integrated on the printed circuit board; and
at least one electronic power supply and signal-processing circuit connected to the antenna and integrated on the printed circuit board;
wherein the four turns are distributed over only two adjacent functional layers, and in that the at least one electronic power supply and signal-processing circuit is formed in at least one functional layer of the printed circuit board that is distinct from the functional layers receiving the turns, the at least one electronic power supply and signal-processing circuit being inscribed inside a surface delimited by an internal contour of the turns.

2. The device as claimed in claim 1, wherein the antenna is formed by four turns, with two first turns located on a first functional layer and two second turns located on a second functional layer, the first functional layer and the second functional layer being separated from each other by a single insulating layer.

3. The device as claimed in claim 2, wherein the two first turns are superposed in pairs with the two second turns.

4. The device as claimed in claim 1, wherein said two adjacent functional layers include an end layer of the printed circuit board.

5. The device as claimed in claim 1, further comprising a capacitive electrode which is inscribed inside a surface delimited by an internal contour of the turns and which is connected to a detection circuit to form a capacitive presence sensor, with the detection circuit integrated on the printed circuit board.

6. The device as claimed in claim 1, wherein each turn is square in shape.

7. A door handle for a motor vehicle, comprising a device as claimed in claim 1.
